(19) United States
(12) Patent Application Publication
(10) Pub. No.: US 2025/0160213 A1
(43) Pub. Date: May 15, 2025

(54) High Thermoelectric Performance in p-type AgSbTe2 Alloys

(71) Applicant: The Penn State Research Foundation, University Park, PA (US)

(72) Inventors: Yu Zhang, State College, PA (US); Bed Poudel, State College, PA (US); Shashank Priya, State College, PA (US)

(21) Appl. No.: 18/836,716

(22) PCT Filed: Feb. 23, 2023
(86) PCT No.: PCT/US2023/063140

§ 371 Date: Aug. 7, 2024

Related U.S. Application Data
(60) Provisional application No. 63/313,445, filed on Feb. 24, 2022.

(51) Int. Cl. H10N 10/01; C01B 19/00

(52) U.S. Cl. CPC H10N 10/01; C01B 19/002; C01P 2002/52; C01P 2002/72; C01P 2002/85; C01P 2002/88; C01P 2004/03; C01P 2006/32; C01P 2006/40

(57) ABSTRACT

Disclosed is a method of forming a p-type semiconductor material. The method can involve synthesizing an AgSbTe₂ compound. During the synthesis, the AgSbTe₂ compound can be doped to replace a Te²⁻ and/or a Sb³⁺ in a lattice structure of the AgSbTe₂ compound with an anion and/or a cation to increase hole concentration of the AgSbTe₂ compound and/or to suppress formation of an Ag₂Te impurity phase of the AgSbTe₂ compound. A p-type semiconductor material can be formed using the anion-doped AgSbTe₂ compound.

### CROSS-REFERENCE TO RELATED APPLICATIONS

This patent application is related to and claims the benefit of U.S. provisional patent application 63/313,445, filed on Feb. 24, 2022, the entire contents of which is incorporated by reference.

### STATEMENT REGARDING FEDERALLY SPONSORED RESEARCH OR DEVELOPMENT

This invention was made with government support under Contract No. W31P4Q-20-C-0047 awarded by the United States Army/Aviation and Missile Command. The Government has certain rights in the invention.

### FIELD OF THE INVENTION

The present invention relates to the field of thermoelectric materials and thermoelectric applications. Embodiments can relate to methods resulting in phase stability and figure-of-merit (zT) enhancement of thermoelectric materials, and specifically AgSbTe_{2-x-y}SeₓS_{y} (0≤x≤0.3, 0≤y≤0.3) and/or AgSb₁₋ₓSnₓTe₂ thermoelectric materials.

### BACKGROUND OF THE INVENTION

Thermoelectric materials (e.g., materials providing a direct route for heat-to-electricity conversion) have attracted great attention in waste heat recovery, power generation, and refrigeration. Thermoelectric energy conversion efficiency for these materials can be determined by dimensionless figure-of-merit, zT (=S²σ/κ), where S, σ and κ stands for Seebeck coefficient, electrical conductivity, and thermal conductivity, respectively. As can be seen, the criteria of high zT thermoelectric materials are those with a low K and a large power factor (S²σ), which depend on transports charge carriers and phonons.

The focus of recent research in the field of thermoelectric materials has been the utilization of defect engineering to increase the zT. This has resulted in the improvement of chalcogenide systems, such as Sn—Te, Sn—Se Pb—Te and Ge—Te compounds with zT>2, capable of operation in the middle/high temperature ranges.

AgSbTe₂ related compounds have attracted significant interest not only owing to their transport properties but also for chalcogenide systems such as LAST and TAGS. They are also included as optical phase-adjust materials. These compounds are promising candidates for application in high-efficiency thermoelectric semiconductors that demonstrate high Seebeck coefficients and low thermal conductivities. The low thermal conductivity is attached to phonon scattering by the disordered occupation of Ag and Sb atoms in the face-centered cubic (FCC) lattice. Recently, Cd doped AgSbTe₂ has been reported to enhance the cationic ordering. The doped material system displayed an ultrahigh thermoelectric property with the spontaneous formation of nanoscale superstructures. The formation of the nanostructures results in ultra-low lattice thermal conductivity. It was demonstrated that the high thermoelectric property of AgSbTe₂ can be attributed to an extremely low thermal conductivity of 0.4 W/m·K and a high Seebeck coefficient ˜280 μV/K.

### SUMMARY OF THE INVENTION

Low thermal conductivity and large Seebeck coefficient make the AgSbTe₂ compound a very promising candidate for high efficiency p-type thermoelectric applications. Anion Se²⁻, S²⁻ doping in Te²⁻ sites in AgSbTe₂ and/or cation Sn²⁺ doping Sb³⁺ sites increases the p-type carrier concentration in this material, which boosts the electrical conductivity of AgSbTe_{2-x-y}SeₓS_{y} and/or AgSb₁₋ₓSnₓTe₂. Substitution of Se, S, Sn in AgSbTe₂ also suppresses the formation of intrinsic Ag₂Te impurity phases. Ag₂Te impurity has a negative impact on the thermoelectric properties of AgSbTe₂ because of its n-type conduction and structural phase transition at ˜425 K. Thus, blocking the formation of the Ag₂Te impurity during synthesis of AgSbTe₂ can be beneficial for optimization of the thermoelectric and mechanical properties of AgSbTe₂. As will be demonstrated herein, the lattice thermal conductivity for exemplary AgSbTe_{2-x-y}SeₓS_{y} and AgSb₁₋ₓSnₓTe₂ samples is reasonably reduced compared to that of the pristine AgSbTe₂. This can be attributed to significant solid solution point defect phonon scattering.

Another major drawback of the AgSbTe₂ compound is its low electrical conductivity caused by the heavy hole carriers, which are due to the effect of the flat valence band maximum.

Furthermore, the heavy atomic masses and the relative weak chemical bonds between Ag, Sb and Te make all atoms weakly bounding to the AgSbTe₂ lattice. The Ag binding is the weakest, which implies that the formation of an Ag vacancy is energetically easy and therefore may be the source of the p-type carriers. Thus, adding excess Te in the AgSbTe₂ lattice can increase the cation vacancy concentration, and so does the hole concentration. In addition, the point defects accompanying the presence of cation vacancy in the lattice of AgSbTe₂ can notably enhance the scattering effects on phonon behavior and result in the reduction of the thermal conductivity.

Incorporating of Se and S can make the system a narrow band gap semiconductor with relatively high electrical conductivity. An advantage of Se/S/Sn substitution in the AgSbTe₂ structure can be suppressing formation of the impurity phase Ag₂Te in AgSbTe_{2-x-y}SeₓS_{y} and/or AgSb₁₋ₓSnₓTe₂. Powder X-ray diffraction and differential scanning calorimetry testing confirmed the gradual suppression of the Ag₂Te impurity phase with increasing Se concentration. Over two orders-of-magnitude difference in their carrier density was determined: for reference AgSbTe₂ sample n_{H}=1.2×10¹⁸ cm⁻³ and for S doped AgSbTe_{1.85}S_{0.15} (x=0, y=0.15) n_{H}=2.0×10²⁰ cm⁻³ at 300 K.

At the same time, the characteristic the mobility behavior exhibits an opposite trend. As a comparison, carrier concentration and mobility of S/Se/(Se+S)/Sn-doped sample show stable and minor variation over the full temperature range. S/Se/(Se+S)/Sn-doped AgSbTe₂ compounds, however, boosts two times higher electric conductivity compared with pristine AgSbTe₂, while doped materials still maintain relatively high Seebeck coefficients, leading to an enhanced power factor as high as 2.0 at 673 K. The enlarged power factor at elevated temperatures for the S-doped compound is mainly due to the increased electrical conductivity.

All doped samples had lower total thermal conductivity and lower lattice thermal conductivity than ternary compounds at high temperature. As a result, the peak value of zT=0.74 at 673 K was detected in the undoped sample, while the maximum zT value was achieved as high as 2.3 at 673 K in the y=0.15 sample. This zTvalue is 310% higher than that of the undoped sample.

Embodiments can relate to a method of improving a thermoelectric property of a p-type semiconductor. The method can involve replacing a Te²⁻ in a lattice structure of a p-type semiconductor material with an anion to increase hole concentration of the p-type semiconductor material and/or to suppress formation of a Ag₂Te impurity phase of the p-type semiconductor material. In addition or in the alternative, the method can involve replacing a Sb³⁺ in the lattice structure of the p-type semiconductor material with a cation to increase hole concentration of the p-type semiconductor material and/or to suppress formation of a Ag₂Te impurity phase of the p-type semiconductor material.

In some embodiments, replacing the Te²⁻ with the anion and/or replacing the Sb¹⁺ with the cation can increase hole concentration of the p-type semiconductor material and suppress formation of a Te impurity phase.

In some embodiments, the p-type semiconductor material can include an AgSbTe₂ compound.

In some embodiments, the p-type semiconductor material can include a semiconductor material in addition to the AgSbTe₂ compound.

In some embodiments, the cation has an ion radius that is less than an ion radius of Sb.

In some embodiments, the anion can have an ion radius that is less than an ion radius of the Te²⁻.

In some embodiments, replacing the Te²⁻ can involve replacing a first Te²⁻ in the lattice structure with a first anion and replacing a second Te²⁻ in the lattice structure with a second anion, the first anion being a different type of anion from the type of anion of the second anion. Replacing the Sb⁺³ can involve replacing a first Sb³⁺ in the lattice structure with a first cation and replacing a second Sb³⁺ in the lattice structure with a second cation, the first cation being the same type of cation as the type of cation of the second cation.

In some embodiments, the first anion can have an ion radius that is less than an ion radius of the first Te²⁻ and the second anion can have an ion radius that is less than an ion radius of the second Te²⁻. The first cation can have an ion radius that is less than an ion radius of Sb³⁺ and the second cation can have an ion radius that is less than an ion radius of Sb³⁺.

In some embodiments, the anion can be Se²⁻ and/or S²⁻. The cation can be Sn²⁺.

In some embodiments, the p-type semiconductor material can include an AgSbTe₂ compound. The anion can be Se²⁻ and/or S²⁻. The cation is Sn²⁺. The doped AgSbTe₂ compound can form AgSbTeSe, AgSbTeS, AgSbSnTe, AgSbSnTeSe, and/or AgSbSnTeS.

In some embodiments, the first anion can be Se²⁻ and the second anion can be S²⁻. The first cation can be Sn²⁺ and the second cation can be Sn²⁺.

In some embodiments, the p-type semiconductor material can include an AgSbTe₂ compound. The first anion can be Se²⁻ and the second anion can be S²⁻. The cation can be Sn²⁺. The doped AgSbTe₂ compound can form AgSbTe_{2-x-y}SeₓS_{y} (0≤x≤0.3, 0≤y≤0.3) and/or AgSb₁₋ₓSnₓTe₂.

In some embodiments, replacing the Te²⁻ and/or the Sb⁺³ in the lattice structure with the anion and/or the cation can involve doping the p-type semiconductor material with the anion and/or the cation.

In some embodiments, doping can involve diffusion and/or ion implantation.

Embodiments can relate to a method of forming a p-type semiconductor material. The method can involve synthesizing an AgSbTe₂ compound. The method can involve doping the AgSbTe₂ compound, during the synthesis, to replace a Te²⁻ and/or a Sb³⁺ in a lattice structure of the AgSbTe₂ compound with an anion and/or a cation to increase hole concentration of the AgSbTe₂ compound and/or to suppress formation of an Ag₂Te impurity phase of the AgSbTe₂ compound. The method can involve forming a p-type semiconductor material with the doped AgSbTe₂ compound.

In some embodiments, the p-type semiconductor material can consist of the doped AgSbTe₂ compound. In some embodiments, the p-type semiconductor material can consist essentially of the doped AgSbTe₂ compound. In some embodiments, the p-type semiconductor material can comprise the doped AgSbTe₂ compound.

Embodiments can relate to a p-type semiconductor material. The material can include an AgSbTe₂ compound having a lattice structure, wherein at least one Te²⁻ site and/or at least one Sb¹⁺ site in the lattice structure has an anion in place of the Te²⁻ and/or a cation in place of the Sb¹⁺, the anion having an ion radius that is less than an ion radius of Te²⁻⁻, the cation having an ion radius that is less than an ion radius of Sb³⁺.

In some embodiments, the p-type semiconductor material can include a semiconductor material in addition to the AgSbTe₂ compound.

In some embodiments, the anion can be Se²⁻ and/or S²⁻. The cation can be Sn²⁺.

An exemplary embodiment can relate to a thermoelectric device. The thermoelectric device can include a p-type semiconductor material. The p-type semiconductor material can include an AgSbTe₂ compound having a lattice structure. At least one Te²⁻ site and/or at least one Sb¹⁺ site in the lattice structure can have an anion in place of the Te²⁻ and/or a cation in place of the Sb³⁺. The anion can have an ion radius that is less than an ion radius of Te²⁻. The cation having an ion radius that is less than an ion radius of Sb³⁺.

Further features, aspects, objects, advantages, and possible applications of the present invention will become apparent from a study of the exemplary embodiments and examples described below, in combination with the Figures, and the appended claims.

### BRIEF DESCRIPTION OF THE DRAWINGS

The above and other objects, aspects, features, advantages and possible applications of the present innovation will be more apparent from the following more particular description thereof, presented in conjunction with the following drawings. Like reference numbers used in the drawings may identify like components.

FIG. 1 shows an exemplary method and schematic for enhancing a thermoelectric property of a p-type semiconductor.

FIGS. 2A, 2B, 2C, 2D, 2E, and 2F show thermoelectric properties of AgSbTe2-x-ySexSy, where FIG. 2A shows temperature variation of electrical conductivity (σ), FIG. 2B shows Seebeck coefficient (S), FIG. 2C shows power factor (σS2), FIG. 2D shows total thermal conductivity (κₜₒₜ), FIG. 2E shows lattice thermal conductivity (κ_{L}), and FIG. 2F shows thermoelectric figure of merit.

FIGS. 3A-3E illustrate DFT-calculated defect formation energy, electronic structure, and Seebeck coefficients, wherein FIG. 3A is the defect formation energy of undoped AgSbTe₂, FIG. 3B is the defect formation energy of doped AgSbTe_{2-x-y}SₓSe_{y}, FIG. 3C is the band structure of AgSbTe₂, FIG. 3D is the band structure of AgSbTe_{2-x-y}SₓSe_{y}, FIG. 3E is the calculated Seebeck coefficient as a function of temperature in AgSbTe₂, and FIG. 3F is the calculated Seebeck coefficient as a function of temperature in AgSbTe_{1.82}Se_{0.12}S_{0.06}.

FIG. 4A shows XRD patterns of as-synthesized AgSbTe_{2-x-y}SeₓS_{y} pellets, FIG. 4B shows Hall charge carrier transport properties, and FIG. 4C shows differential scanning calorimetry (DSC) curves and specific heat capacity of AgSbTe₂, AgSbTe_{1.85}Se_{0.15}, and AgSbTe_{1.85}Se_{0.1}S_{0.05} samples.

FIGS. 5A-5D show a unicouple AgSbTe_{1.85}S_{0.15}-based device and power generation performance of the device, wherein FIG. 5A shows schematic diagram of the setup used to test the power and conversion efficiency under vacuum, FIG. 5B shows the current dependent output power of a unicouple thermoelectric device, FIG. 5C the current dependent conversion efficiency of a unicouple thermoelectric device, and FIG. 5D shows a comparison of the maximum conversion efficiency (ηₘₐₓ) as a function of temperature difference of doped p-type AgSbTe₂ unicouple device with that of other state-of-art unicouple/multi-couple devices.

FIG. 6 shows SEM of milled AgSbTe_{1.7}Se_{0.1}S_{0.2} particles and EDX elemental maps of a single particle.

FIG. 7 shows device figure of merit (_{Z}T_{dev}) of S-doped polycrystalline AgSbTe₂ with other state of the art materials.

FIGS. 8A, 8B, 8C, and 8D show reproducibility of thermoelectric properties of AgSbTe_{1.85}Se_{0.1}S_{0.05} among different batches of samples synthesized separately, wherein FIG. 8A shows temperature dependent electrical conductivity, FIG. 8B shows Seebeck coefficient, FIG. 8C shows total thermal conductivity, and FIG. 8D shows thermoelectric zT.

FIG. 9 shows an exemplary sample preparation method.

FIG. 10 shows thermoelectric properties of AgSbTe_{2-x-y}SeₓS_{y}, where graph A shows temperature variation of electrical conductivity (σ), graph B shows Seebeck coefficient(S), graph C shows power factor (σS2), graph D shows total thermal conductivity (κₜₒₜ), graph E shows lattice thermal conductivity (κ_{L}), and graph F shows thermoelectric figure of merit.

FIG. 11 shows thermoelectric properties of AgSb₁₋ₓSnₓTe₂, where graph A shows temperature variation of electrical conductivity (σ), graph B shows Seebeck coefficient(S), graph C shows power factor (σS2), graph D shows total thermal conductivity (κₜₒₜ), graph E shows thermoelectric figure of merit, and image F shows a schematic of an Sn ion replacing a Sb ion.

FIG. 12 shows XRD patterns of as-prepared AgSbTe_{2-x-y}SeₓS_{y} sample (XRD Pattern A) and AgSb₁₋ₓSnₓTe₂ sample (XRD Pattern B).

### DETAILED DESCRIPTION OF THE INVENTION

The following description is of exemplary embodiments that are presently contemplated for carrying out the present invention. This description is not to be taken in a limiting sense, but is made merely for the purpose of describing the general principles and features of the present invention. The scope of the present invention is not limited by this description.

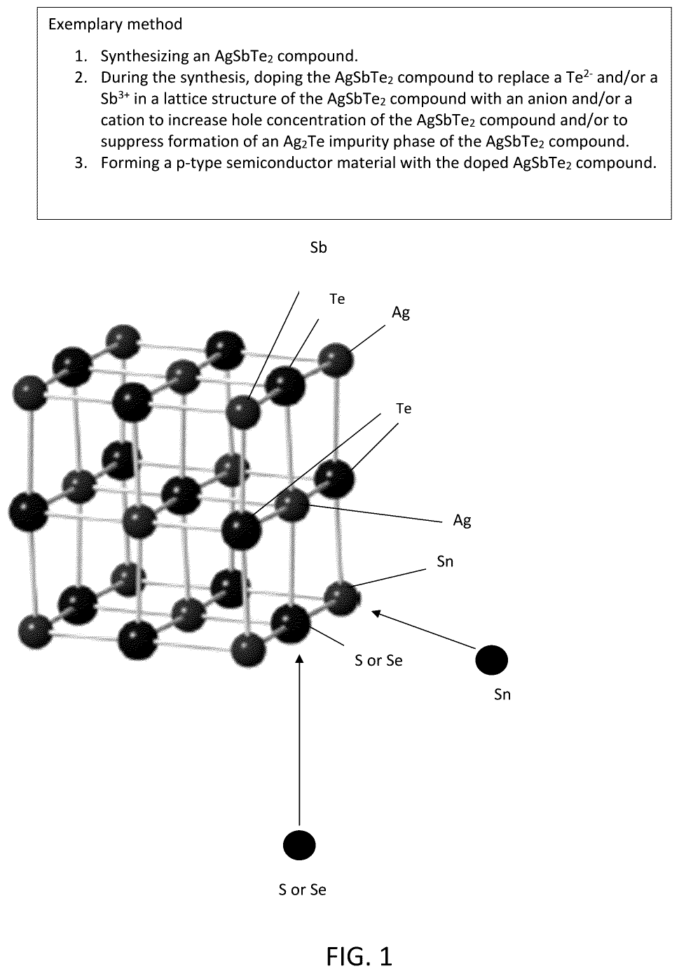

Referring to FIG. 1, embodiments relate to a method of improving a thermoelectric property of a p-type semiconductor. The method can involve replacing a Te²⁻ anion in a lattice structure of a p-type semiconductor material with an anion to increase hole concentration of the p-type semiconductor material and/or to suppress formation of Ag₂Te impurity phase of the p-type semiconductor material. In other words, the Te²⁻ anion is substituted with a different anion in the lattice structure. This substitution can increase hole concentration, suppress formation of a Ag₂Te impurity phase during synthesis of the p-type semiconductor material, or both.

The p-type semiconductor material can include an AgSbTe₂ compound. For instance, the p-type semiconductor material can be a material for which at least a portion thereof is AgSbTe₂. Thus, the p-type semiconductor material can include an AgSbTe₂ compound, the AgSbTe₂ compound having a lattice structure with Te²⁻ sites. For at least one of these Te²⁻ sites, the Te²⁻ is replaced with a different anion. This can be achieved via doping (e.g., diffusion, ion implantation, etc.) the AgSbTe₂ compound with the anion. The resultant p-type semiconductor material can: be made solely of the anion-doped AgSbTe₂ compound; be made as a heterostructure comprising the anion-doped AgSbTe₂ compound and non-doped AgSbTe₂ compound; be made as a heterostructure comprising the anion-doped AgSbTe₂ compound and another semiconductor compound (e.g., GaAs, GaN, SiC, InP, AlGaInP, etc.); be made as a heterostructure comprising the anion-doped AgSbTe₂ compound, non-doped AgSbTe₂ compound, and another semiconductor compound, etc.

In an exemplary embodiment, the method involves synthesizing an AgSbTe₂ compound to form a single crystal of AgSbTe₂ having a lattice structure. The method can involve doping the AgSbTe₂ compound with the anion during the synthesis. Doping the AgSbTe₂ compound with the anion allows the anion to replace at least one Te²⁻ anion at a Te²⁻ site of the lattice structure. This replacement or substitution can reduce (e.g., reduce the amount, reduce the likelihood, etc.) or prevent Ag₂Te impurity phase formation during synthesis.

It is contemplated for the anion to have an ion radius that is less than an ion radius of the Te²⁻. The anion can be Se²⁻ and/or S²⁻, for example. Thus, the p-type semiconductor material can include an AgSbTe₂ compound, wherein the anion can be Se²⁻ and/or S²⁻ such that the anion-doped AgSbTe₂ compound forms AgSbTeSe and/or AgSbTeS.

The method can involve doping the AgSbTe₂ compound with more than one type of anion. For instance, replacing the Te²⁻ anion can involve replacing a first Te²⁻ anion in the lattice structure with a first anion and replacing a second Te²⁻ anion in the lattice structure with a second anion, wherein the first anion is different from the second anion. It is contemplated for the first anion to have an ion radius that is less than an ion radius of the first Te²⁻ anion and for the second anion to have an ion radius that is less than an ion radius of the second Te²⁻ anion. Thus, the p-type semiconductor material can include an AgSbTe₂ compound, wherein the first anion can be Se²⁻ and the second anion can be S²⁻ such that the anion-doped AgSbTe₂ compound forms AgSbTe_{2-x-y}SeₓS_{y} (0≤x≤0.3, 0≤y≤0.3).

As can be appreciated from the disclosure, embodiments can relate to a method of forming a p-type semiconductor material. The method can involve synthesizing an AgSbTe₂ compound. The AgSbTe₂ compound can be doped during the synthesis to replace a Te²⁻ anion in a lattice structure of the AgSbTe₂ compound with an anion to increase hole concentration of the AgSbTe₂ compound and/or to suppress formation of an Ag₂Te impurity phase of the AgSbTe₂ compound. The anion can be Se²⁻ and/or S²⁻. The anion-doped AgSbTe₂ compound can be used to forma a p-type semiconductor material. The p-type semiconductor material can consist of the anion-doped AgSbTe₂ compound, consist essentially of the anion-doped AgSbTe₂ compound, or comprises the anion-doped AgSbTe₂ compound. This can result in a p-type semiconductor material comprising an AgSbTe₂ compound having a lattice structure, wherein at least one Te²⁻ site in the lattice structure has an anion in place of the Te²⁻ anion, the anion having an ion radius that is less than an ion radius of Te²⁻ anion.

### Examples

The following describes examples of implementing the disclosed method and test results of a p-type semiconductor material comprising an AgSbTe₂ compound having a lattice structure, wherein at least one Te²⁻ site in the lattice structure has an anion in place of the Te²⁻ anion.

### Materials and Methods

### Materials

Silver shots (Ag, 1-5 mm, 99.9% Thermo Scientific), antimony shots (Sb, Alfa Aesar 99.9999%), selenium shots (Se, Sigma Aldrich 99.9%), tellurium lumps (Te, Alfa Aesar 99.9%) and sulfur flasks (S, Sigma Aldrich, 99.9%). All chemicals were used as received, without further purification.

### Synthesis

AgSbTe_{2-x-y}SeₓS_{y} samples were synthesized by mixing high-purity elements of Ag, Sb, Te, Se, and S in quartz tubes. The tubes were sealed under vacuum (˜10⁻⁵ Torr) and slowly heated from room temperature to 1173 K over 6 h, keep at 1173 K for another 6 h, then slowly cooled down to room temperature over a period of 10 h. The obtained bulk ingots were hand milled into powder and consolidated by spark plasma sintering (SPS, Dr. Sinter-625V, Fuji, Japan) at 703 K under a pressure of 40 MPa for 2 minutes.

The electrical conductivity and Seebeck coefficient were measured simultaneously (ULVAC-RIKO ZEM-3 system, Japan) using 2 mm×2 mm×12 mm bar. High-temperature thermal properties were determined by measuring thermal diffusivity with a laser flash system (LFA-467 HT HyperFlash®, Germany). Specific heat was measured with a differential scanning calorimeter (Netzsch DSC 214, Germany, heating/cooling rate of 15 K/min). The thermal conductivity, κ=D×ρ×Cp, where D, ρ, and Cp are thermal diffusivity, density, and specific heat, respectively. The density was measured using Archimedes method. The estimated error in thermal conductivity measurement is estimated about ±4%.

Electronic thermal conductivity (κe) of AgSbTe_{2-x-y}SeₓS_{y} was calculated from Wiedemann-Franz law, κe=LσT, where L and o are Lorenz number and electrical conductivity, respectively. The estimated error in electrical conductivity, thermal conductivity, and Seebeck coefficient are ±5, ±2, and ±5, respectively.

### Powder X-Ray Diffraction

X-ray diffraction analyses were carried out on a PANalytical Empyrean with Cu-Kα radiation in 2θ angle range of 10-60°. The microstructure of the samples was investigated by transmission electron microscope (TEM) using a Talos F200X at 200 kV. TEM samples were prepared by focused-ion beam (FIB) technique.

### Results and Discussion

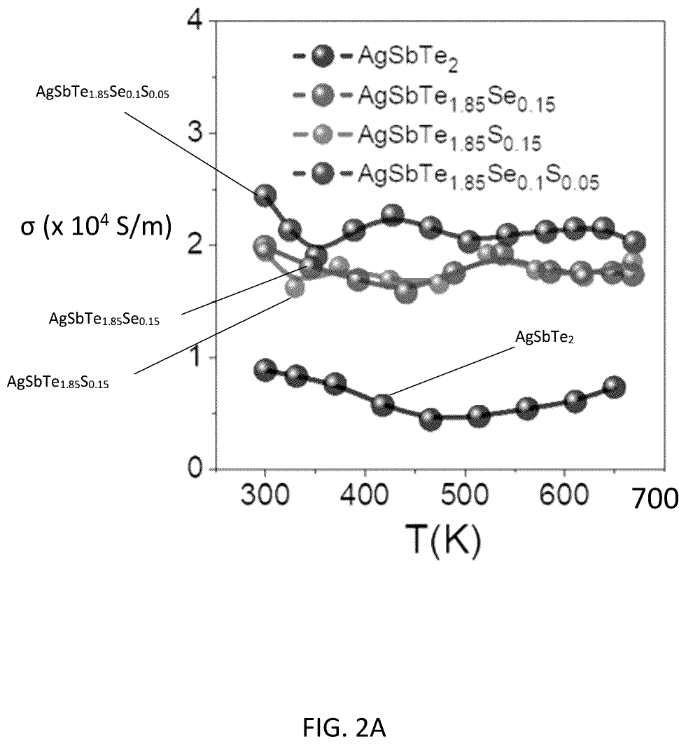

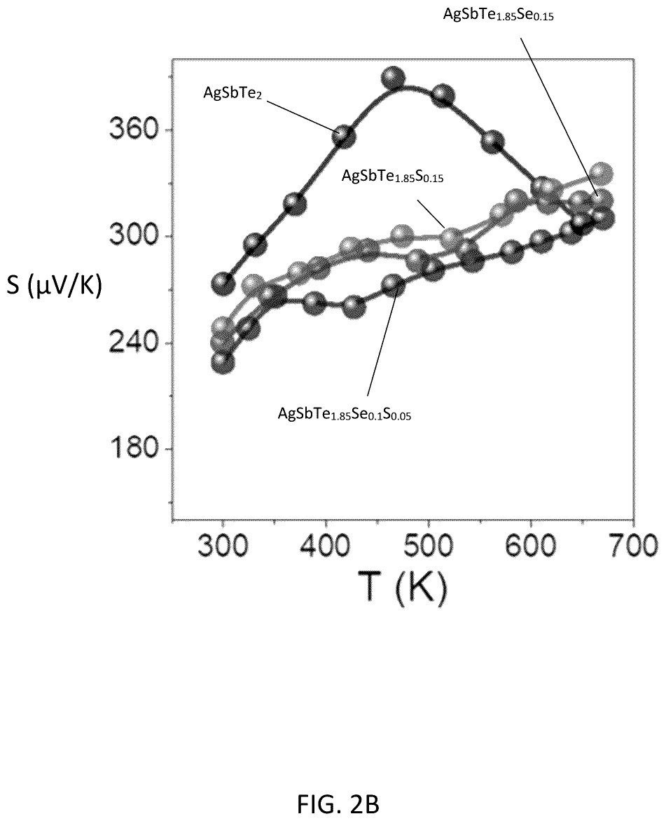

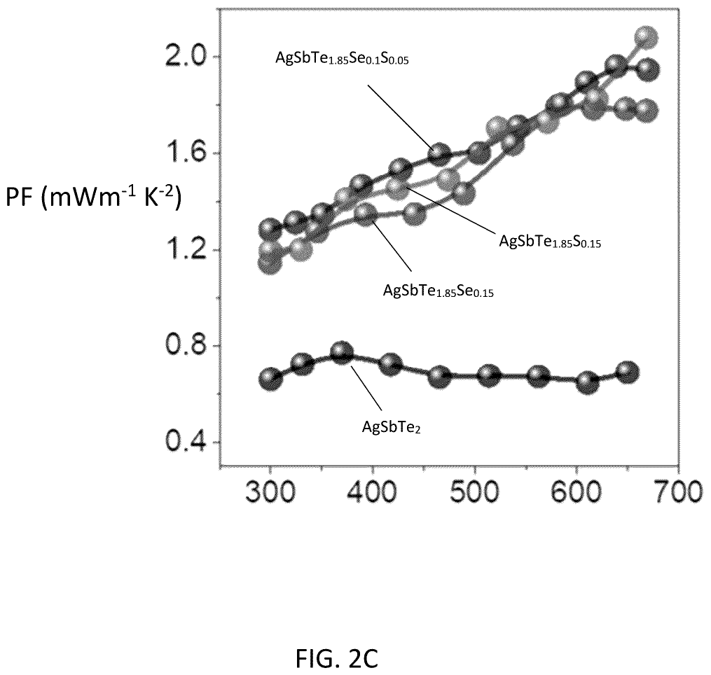

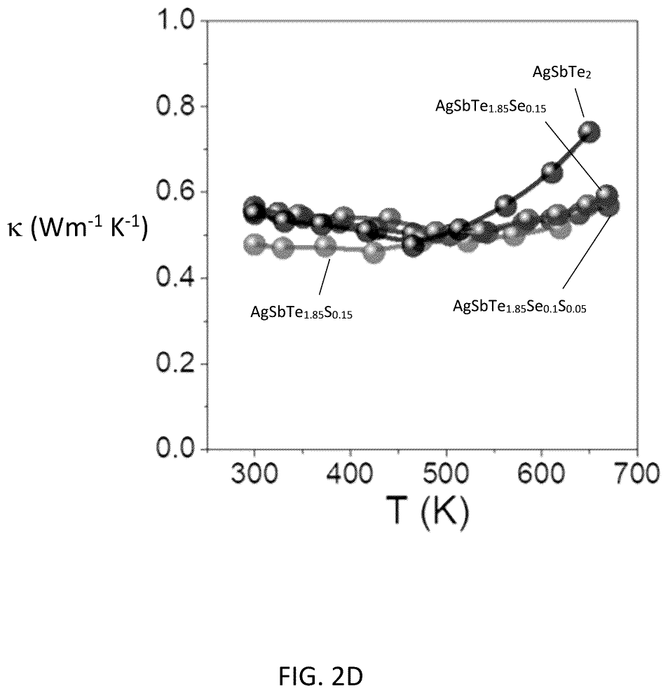

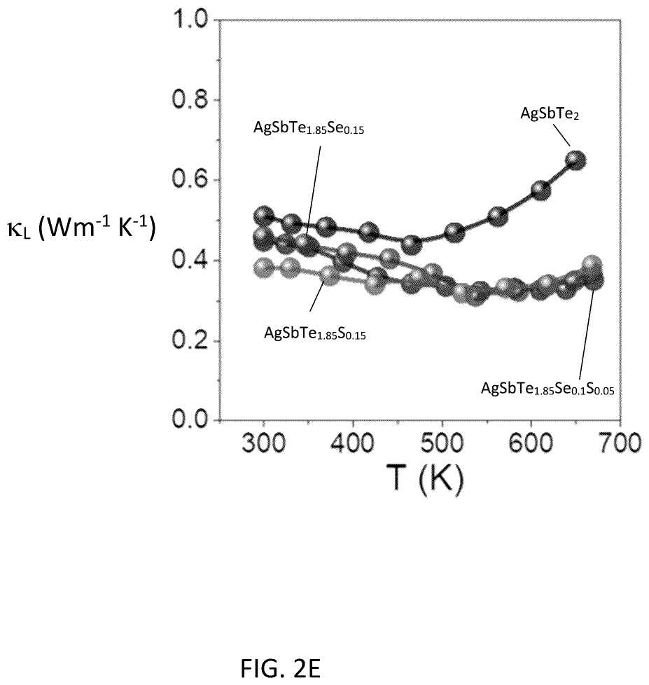

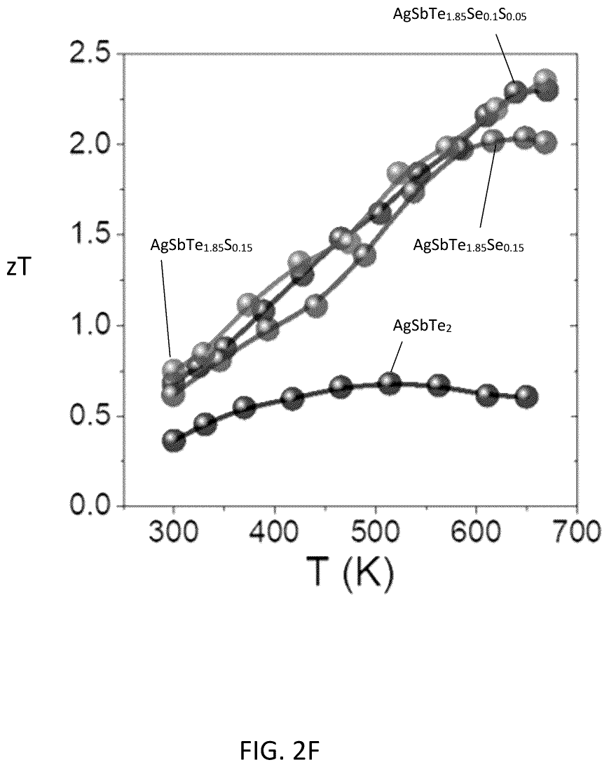

FIGS. 2A, 2B, 2C, 2D, 2E, and 2F show thermoelectric properties of AgSbTe_{2-x-y}SeₓS_{y}, where FIG. 2A shows temperature variation of electrical conductivity (σ), FIG. 2B shows Seebeck coefficient(S), FIG. 2C shows power factor (σS2), FIG. 2D shows total thermal conductivity (kₜₒₜ), FIG. 2E shows lattice thermal conductivity (K_{L}), and FIG. 2F shows thermoelectric figure of merit. These FIG. 2A show that S/Se/(Se+S) doping increases σ significantly throughout the temperature range from near room temperature to 673 K while still maintaining high Seebeck values. PF of AgSbTeSeS remains higher throughout the temperature range from near room temperature to 673 K, as compared to that of the pristine AgSbTe₂. The maximum of PF of AgSbTe_{2-x-y}SeₓS_{y} is ˜21 μW cm⁻¹ K⁻² at 673 K. S/Se/(Se+S) doping in polycrystalline AgSbTe₂ further improves its thermoelectric performance by reducing kₜₒₜ and k_{L}. As a result of this reduced kₜₒₜ and enhanced PF, _{Z}T of S/Se/(Se+S)-doped AgSbTe₂ improves tremendously, achieving a maximum _{Z}T˜2.3 at 673 K.

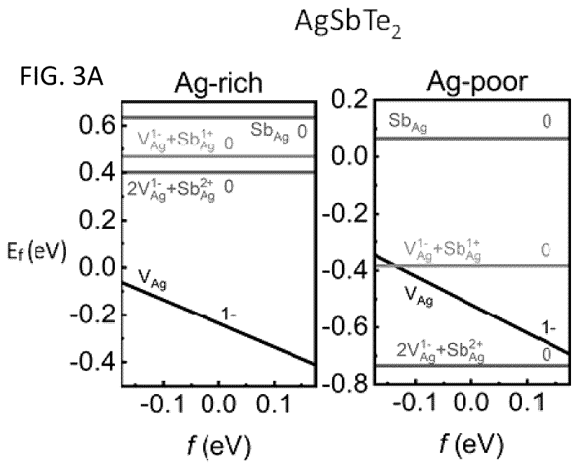

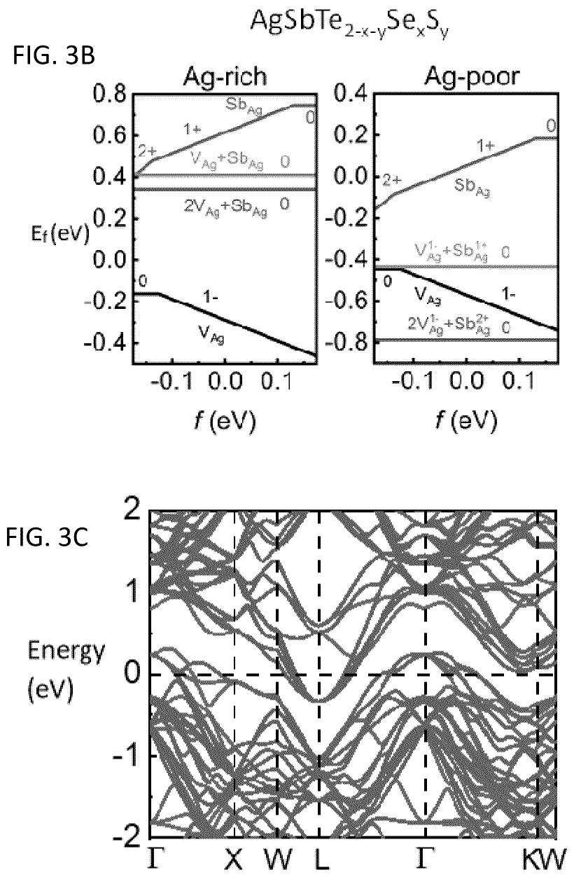

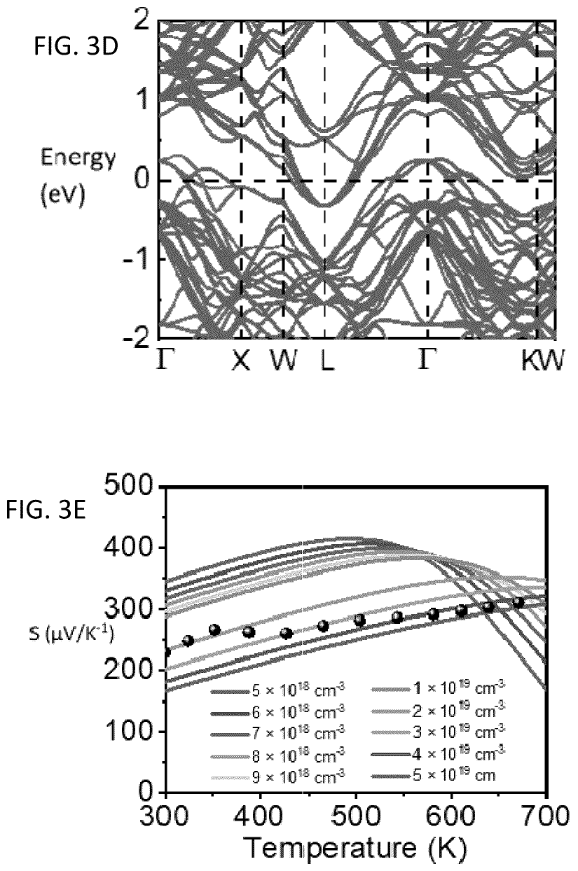

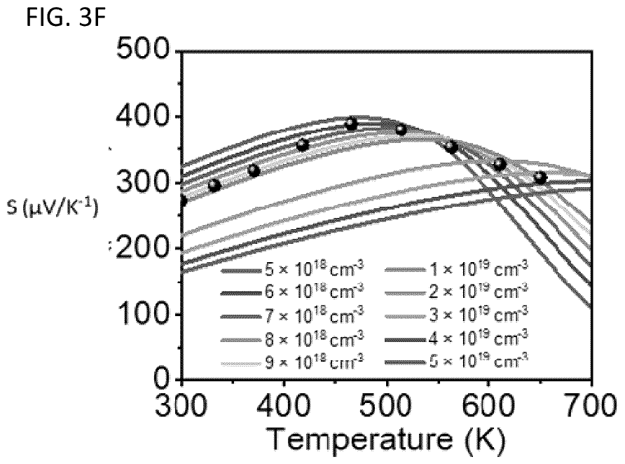

FIG. 3A-3F illustrate DFT-calculated defect formation energy, electronic structure, and Seebeck coefficients. Defect formation energies of individual defects V_{Ag}, Sb_{Ag} and complex defects V_{Ag}⁻+Sb_{Ag}⁺ and 2V_{Ag}⁻+Sb_{Ag}²⁺ with respect to the Fermi level in AgSbTe₂ (FIG. 3A) and AgSbTe_{2-x-y}SₓSe_{y} (FIG. 3B). Band structure of AgSbTe₂ (FIG. 3C) and AgSbTe_{1.82}Se_{0.12}S_{0.06} (FIG. 3D). Calculated Seebeck coefficient as a function of temperature in AgSbTe₂ (FIG. 3E) and AgSbTe_{1.82}Se_{0.12}S_{0.06} (FIG. 3F), considering hole concentrations in the range from 5×10¹⁸ cm⁻³ to 5×10¹⁹ cm⁻³. Experiment data is plotted using black dots.

Temperature variation of S of AgSbTe_{2-x-y}SeₓS_{y} (x=0 to 0.2) exhibits overall reduction in S with increasing S concentration. The near-room temperature S decreases from ˜273 μV K⁻¹ for pristine AgSbTe₂ to ˜229 μV K⁻¹ in x=0.05 S-doped AgSbTeSe. As a result of this large enhancement in σ while maintaining a high S, σS² of S-doped AgSbTeSe remains higher throughout the temperature range from near room temperature to 673 K than that of the pristine AgSbTe₂. The near-room temperature value of σS² of AgSbTe_{2-x-y}SeₓS_{y} composition (˜12.8 μW cm⁻¹ K⁻²) is substantially higher than that of the pristine AgSbTe₂ (˜6.6 μW cm⁻¹ K⁻²). The maximum of σS² of AgSbTe_{2-x-y}SeₓS_{y} is ˜21 μW cm⁻¹ K⁻² at 673 K. All S/Se-doped samples had lower total thermal conductivity and lower lattice thermal conductivity than the ternary compound at high temperature. As a result, the peak value of/T=0.74 at 673 K was detected in the undoped sample, while the maximum _{Z}T value was achieved as high as 2.2 at 673 K in the x=0.15 sample. This _{Z}T value is 290% higher than that of the undoped sample.

The effect of temperature-dependent thermoelectric performance of Bi/Ce/Sn/Ce/Cd/S-doped AgSbTe_{1.85}Se_{0.15} compounds was investigated. Cd and Bi doped samples display lower electrical conductivity compared with reference AgSbTe_{1.85}Se_{0.15}. Specifically, the Bi doped sample shows two-time smaller values between 300 K and 600 K, which boost higher Seebeck coefficients up to 380 μV/K around 450 K. On the other end, Ce, Cd, Sn, and S doped samples demonstrate improvement in elevating electrical conductivity. Among them, the Sn doped sample shows highest values between 350-650 K. Overall, the result of Seebeck coefficient evolution is inversely correlated to σ. Higher values are detected in samples doped with Bi and Cd, while the rest dopants contribute to lower S. A maximum power factor, as high as 1.98 mW/m·K² at 650 K, was achieved in sulfur doped AgSbTe_{1.85}Se_{0.15}, which is came from enhanced σ with minor reduction on S. As a consequence, S doping can boost a high _{Z}T up to 2.2 at 673 K, indicating that the sulfur dopant influences the structure of AgSbTe_{1.85}Se_{0.15}.

Electrical transports of AgSbTe₂ have the contribution from both low mobility heavy holes (higher concentration) and highly mobile light electrons (lower concentration) as it has semi-metallic electronic structure with flat valence band and narrow conduction band. At room temperature, the pristine AgSbTe₂ has a hole concentration of ˜1.2×10¹⁸ cm⁻³ and hole mobility of ˜288 cm² V⁻¹ s⁻¹, which is similar to previous results. In AgSbTeSe, S doping increases the room-temperature hole concentration to ˜2.8×10²⁰ cm⁻³. However, the room-temperature hole mobility in 6 mol % S-doped AgSbTeSe is ˜6.3 cm² V⁻¹ s⁻¹, which is significantly lower than the pristine AgSbTe₂ value. Two important aspects are clear from the temperature-dependent Hall mobility of holes. First, hole mobility (μp) monotonously increases with temperature in pristine AgSbTe₂, while rather a stable trend was characterized in S doped AgSbTe₂. However, the hole mobility (μp) in Se/S-doped AgSbTe₂ increases monotonously with decreasing temperature in the measured temperature range. Second, although Se/S doping increases the hole concentration to ˜2.8×10²⁰ cm⁻³ from the value of 1.2×10¹⁸ cm⁻³ in pristine AgSbTe₂ at 300 K, the degradation in hole mobility is also large. Both of these aspects demonstrate the substantial role of S doping-induced enhancement in electrical transport of AgSbTe₂.

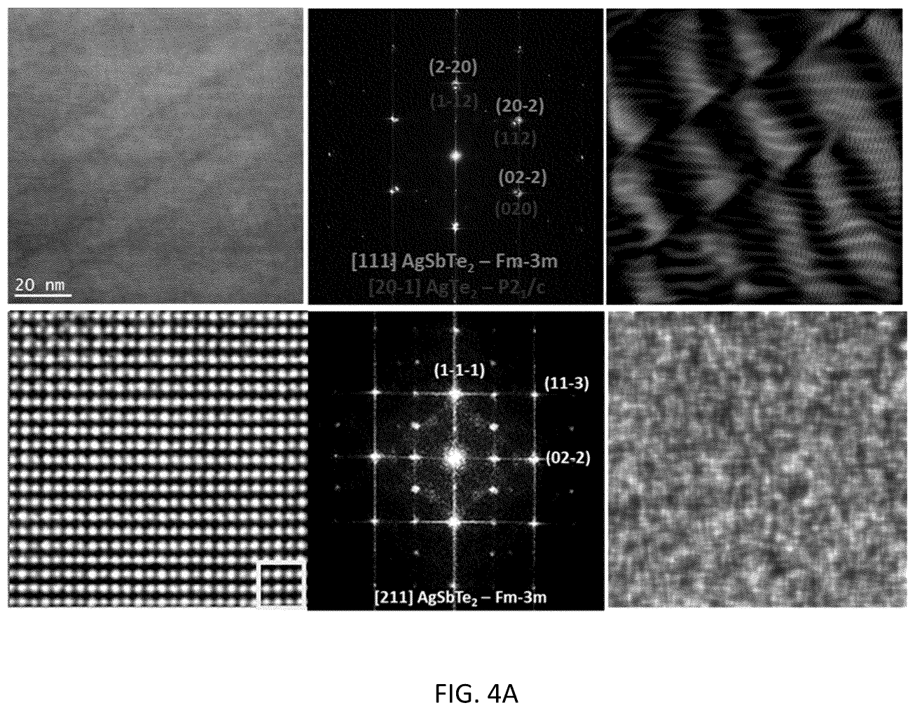

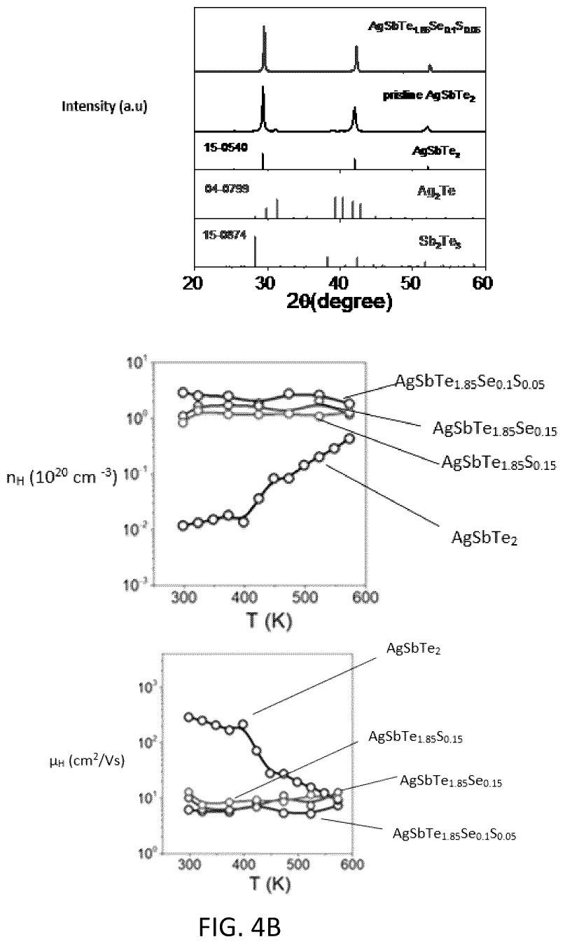

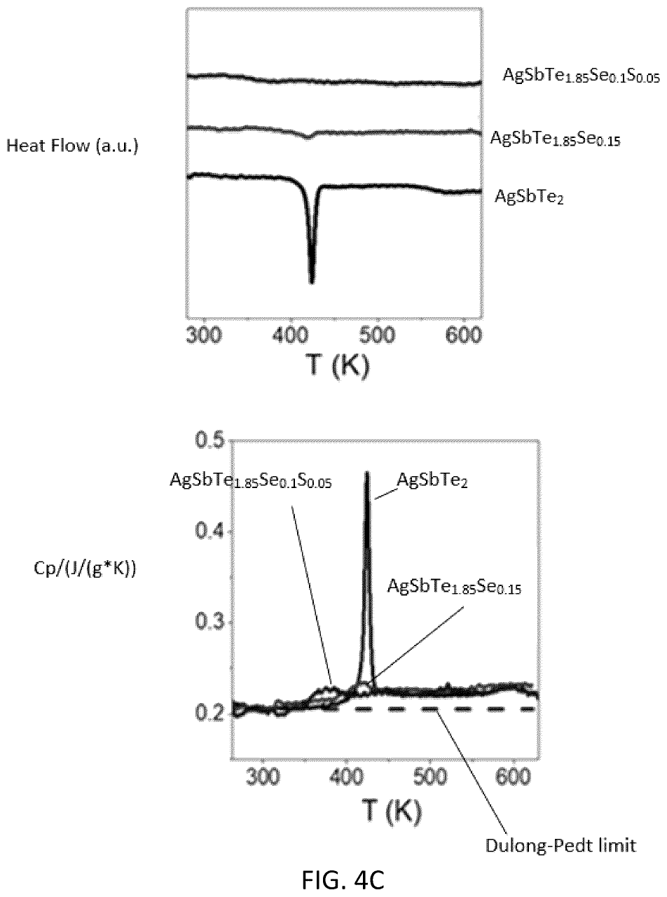

FIG. 4A shows XRD patterns of as-synthesized AgSbTe_{2-x-y}SeₓS_{y} pellets, FIG. 4B shows Hall charge carrier transport properties, and FIG. 4C shows differential scanning calorimetry (DSC) curves and specific heat capacity of AgSbTe₂, AgSbTe_{1.85}Se_{0.15}, and AgSbTe_{1.85}Se_{0.1}S_{0.05} samples. HR-STEM images were obtained from the inner structure of a single grain. Corresponding FFT of the HR-STEM image were also obtained. A composite map of the diffraction spots, corresponding to the fcc AgSbTe₂ and monoclinic AgTe₂ phases, respectively, were also obtained.

As indicated above, FIG. 4 shows the XRD patterns of the melting growth alloys AgSbTe_{2-x-y}SeₓS_{y} (x=0, y=0; and x=0.1, y=0.05, respectively). The majority characteristic peaks can be indexed as the cubic rocksalt type AgSbTe₂ phase (JCPDS No. 0150540). A minor amount of secondary phase, denoted by downward arrows, can be indexed as Ag₂Te. An enlargement of the XRD peak position at 2θ=27.5-31°, shown on the right side, clearly indicates the characteristic peaks of the AgSbTe₂ phase shift to higher angles when the S and Se substitution. This implies that there is a decrease in the lattice parameters, which is expected as a result of substitution of the larger ion radius of Te²⁻ (ion radius 2.21 A°) by S²⁻ (ion radius 1.84 A°) and Se²⁻ (ion radius 1.98 A°). Furthermore, XRD analyses demonstrate that Se/S doping can effectively suppress the formation of Ag₂Te impurity phase.

XRD peaks of undoped AgSbTe₂ can be well indexed to cubit Fm3m AgSbTe₂ standard card, however, a minute impurity peak at 31.2° was detected, which was identified as Ag₂Te secondary phase. As a comparison, XRD peaks of samples prepared by S/Se/(Se+S) doping are completely matched with the standard card, with no impurity phase detected. The results suggest that S/Se/(Se+S) doping is able to produce a pure phase AgSbTe₂.

Temperature dependence of carrier density n_{H} and hall mobility μ_{H} were investigate for pristine and S/Se doped AgSbTe₂ samples. Over two orders-of-magnitude difference in carrier density was determined. Reference AgSbTe₂ sample exhibited n_{H}=1.2×10¹⁸/cm³. Se doped AgSbTe_{1.85}Se_{0.15} exhibited n_{H}=2.0×10²⁰/cm³ at 300 K. A larger temperature-independent concentration of carriers is observed in the pristine AgSbTe₂ sample, where carrier density gradually increased with temperature 300-400K while rapidly rose between 400 K and 573K. At the same time, the characteristic the mobility behavior exhibits an opposite trend. As a comparison, carrier concentration and mobility of Se/(Se+S) doped sample showed stable and minor variation over the full temperature range. Apart from XRD analysis, the reduced amount/proportion of Ag₂Te was also confirmed by differential scanning calorimetry (DSC) and Cp measurements. The endothermic peaks at 423K can be observed in both DSC and Cp curves. The peak at 423K corresponds to the phase transition peaks from α-Ag₂Te to β-Ag₂Te. The intensity of the peak at 423K is distinctly lower for the AgSbTe_{1.85}Se_{0.15} sample. In addition, after doping with sulfur, the ratio of Ag₂Te was furthermore decreased.

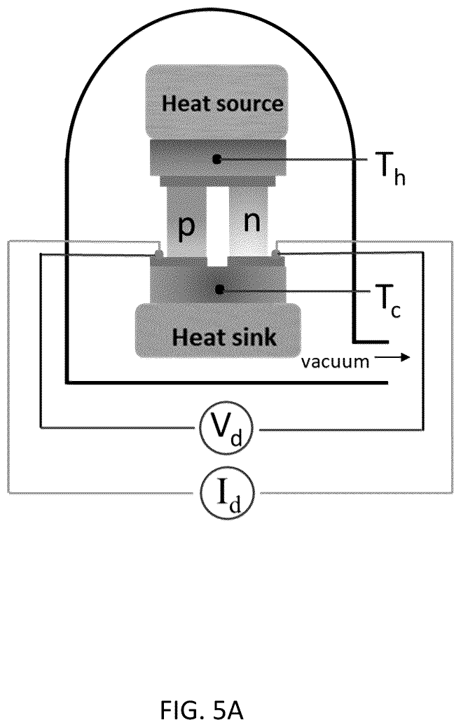

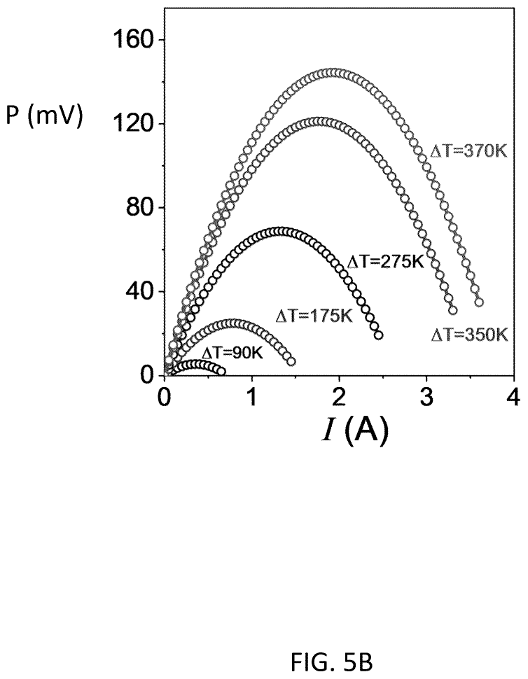

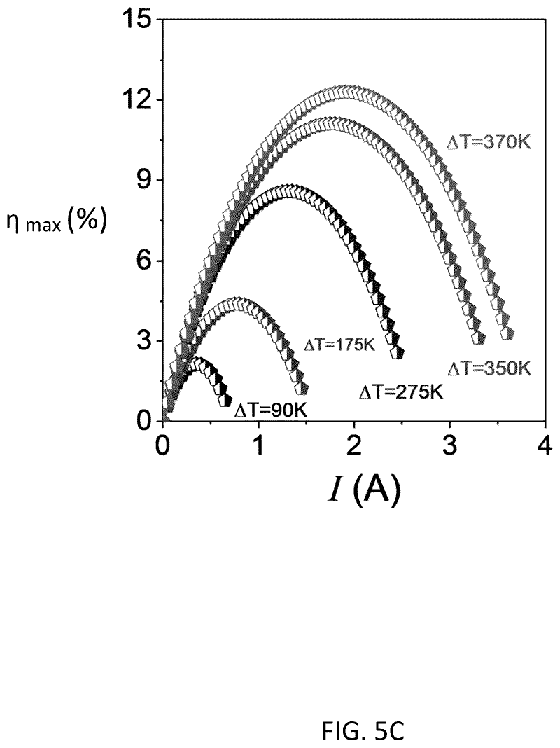

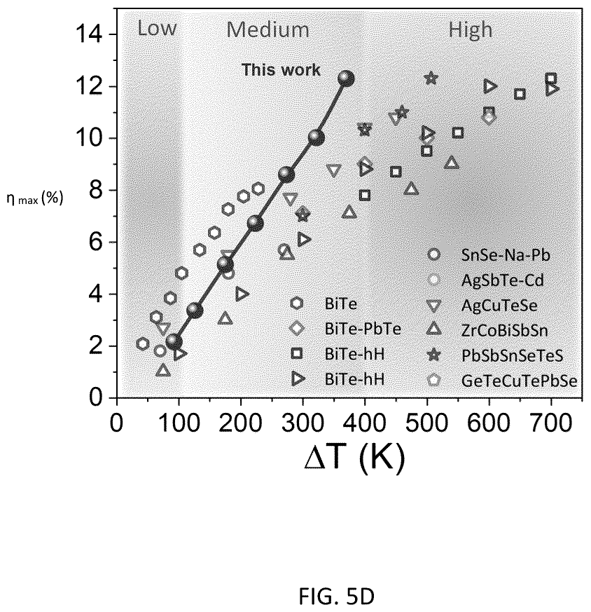

FIGS. 5A-5D show an exemplary AgSbTe_{1.85}S_{0.15} device and power generation performance of the device, wherein FIG. 5A shows exemplary schematics and a prototype of a thermoelectric device, FIG. 5B shows output power v. current for the device, FIG. 5C shows conversion efficiency of the device, and FIG. 5D shows the comparison of the maximum conversion efficiency (ηₘₐₓ) as a function of temperature difference of doped p-type AgSbTe₂ unicouple device with that of other state-of-art unicouple/multi-couple devices. To demonstrate the high thermoelectric efficiency enabled by the high-zT AgSbTe alloys, a single-leg thermoelectric device was fabricated using AgSbTe_{1.85}S_{0.15} with a dimension of ˜3 mm by 3 mm by 4.5 mm. Au was deposited on top and bottom side of leg as diffusion barrier layer. In addition, Au was confirmed to bond well with AgSbTe with a negligible chemical diffusion. This enabled a robust bonding without any cracks, as confirmed by SEM observations taken before and after thermal cycling and long-term stability test. Note that the Au diffusion barrier layer is only ˜200 nm in thickness and Au has a much higher thermal conductivity as compared to that of AgSbTe₂ alloys at room temperature. Therefore, a large temperature gradient loss due to such a diffusion barrier was not expected.

With a fixed cold side temperature of ˜300 K, the output voltage (V) as a function of different temperature gradients (ΔT) is tested. The linearity of V-I curves enables a determination of open-circuit voltage (Voc) and the internal resistance (Ri), respectively. The increase in Voc with increasing ΔT can be understood by the increase in Seebeck coefficient of AgSbTe alloys. The maximum output power is ˜75 mW at ΔT˜370 K.

Efficiency (η) under different temperature gradients (ΔT) was investigated, and a measured maximum efficiency (ηₘₐₓ) was realized to be as high as ˜14% at ΔT=370 K, which is actually higher than any of the experimental results in various devices reported before. Note that the ηₘₐₓ obtained is highly comparable to that of conventional Bi₂Te₃ devices and the recently reported MgAgSb near room temperature (ΔT<250 K), which can be understood by their comparable zT as well as the stable and high compatibility factor of AgSbTe alloys at these temperatures.

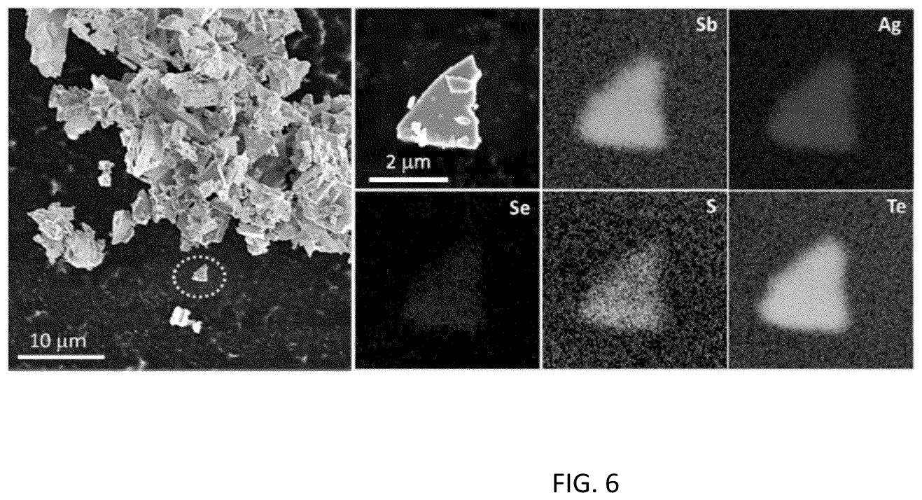

FIG. 6 shows SEM of milled AgSbTe_{1.7}Se_{0.1}S_{0.2} particles and EDX elemental maps of a single particle. The EDS profile taken from a representative random particle was confirmed to be composed of Ag, Sb, Te, S, and Se. According to EDS mappings, these elements distributed evenly. Based on the added SEM characterization and the previously provided XRD patterns, there was no detectable impurity in the S/Se/(Se+S) samples.

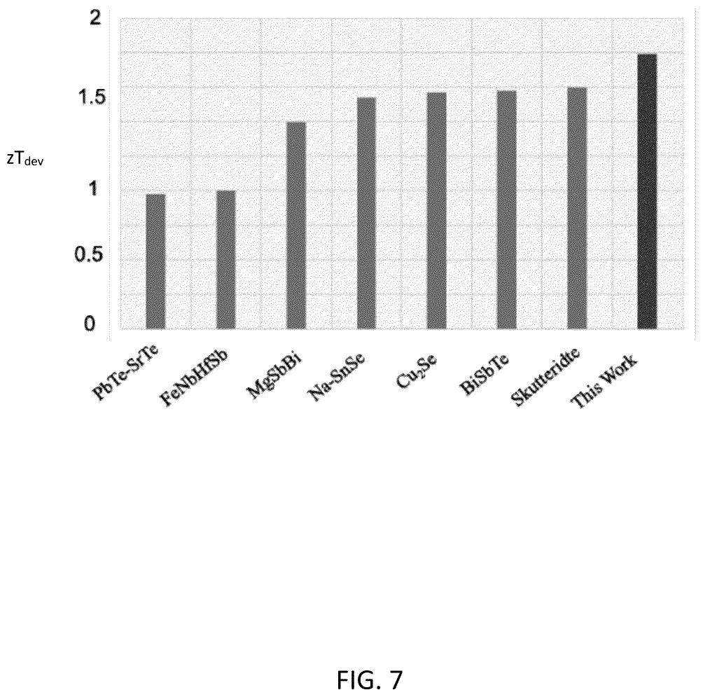

FIG. 7 shows device figure of merit (zT_{dev}) of S-doped polycrystalline AgSbTe₂ with other state of the art materials. zT_{dev} was calculated for the entire measured temperature range. A record zT_{dev} over 1.6 was secured, which can outperform the state of the art thermoelectric materials.

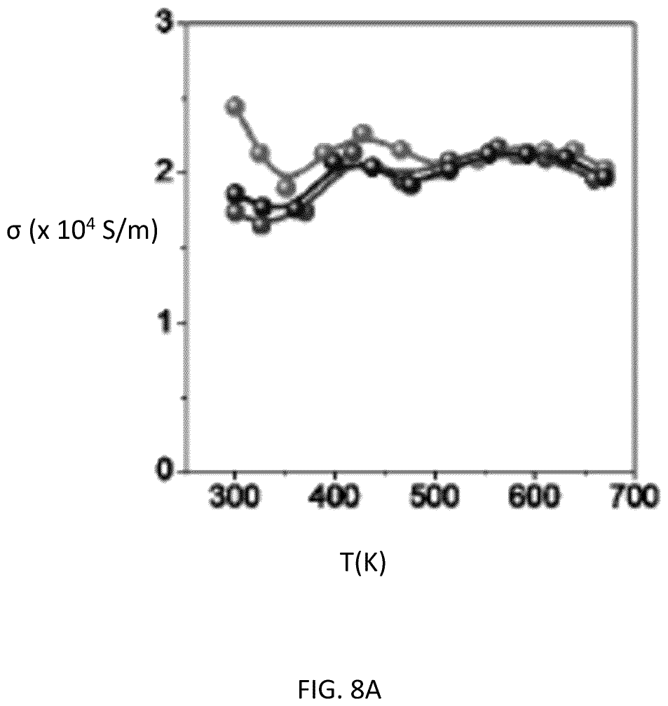

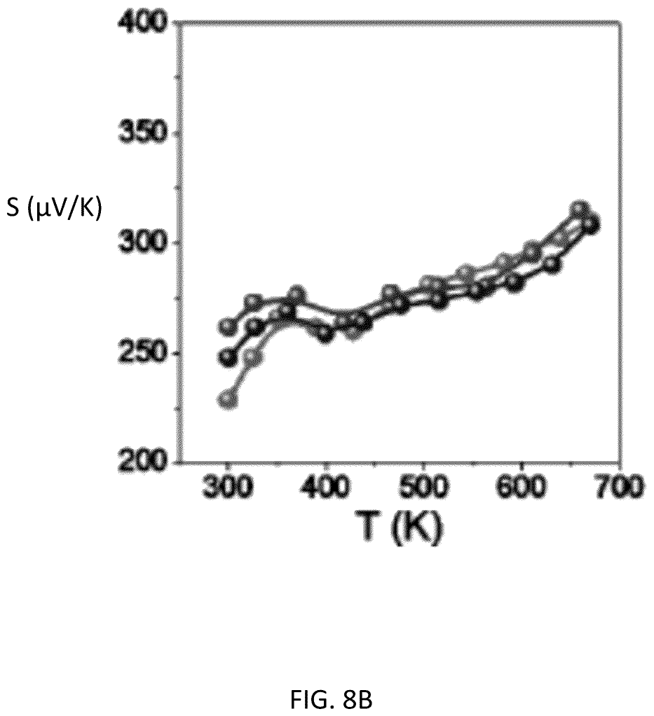

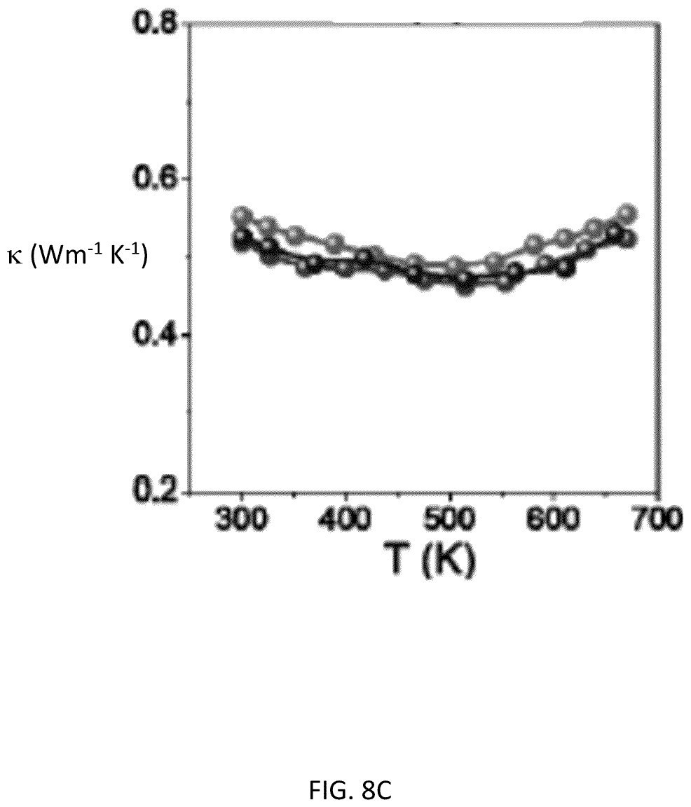

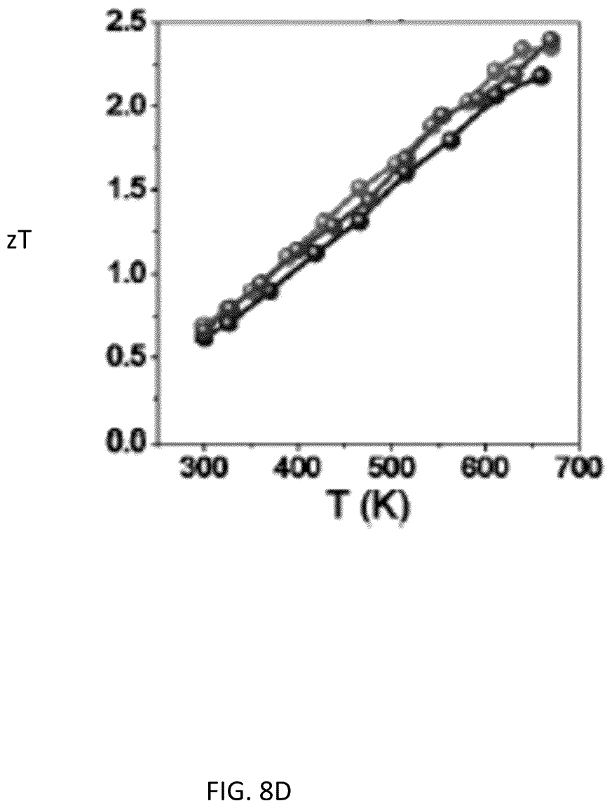

FIGS. 8A, 8B, 8C, and 8D show reproducibility of thermoelectric properties of AgSbTe_{1.85}Se_{0.1}S_{0.05} among different batches of samples synthesized separately, wherein FIG. 8A shows temperature dependent electrical conductivity, FIG. 8B shows Seebeck coefficient, FIG. 8C shows total thermal conductivity, and FIG. 8D shows thermoelectric zT.

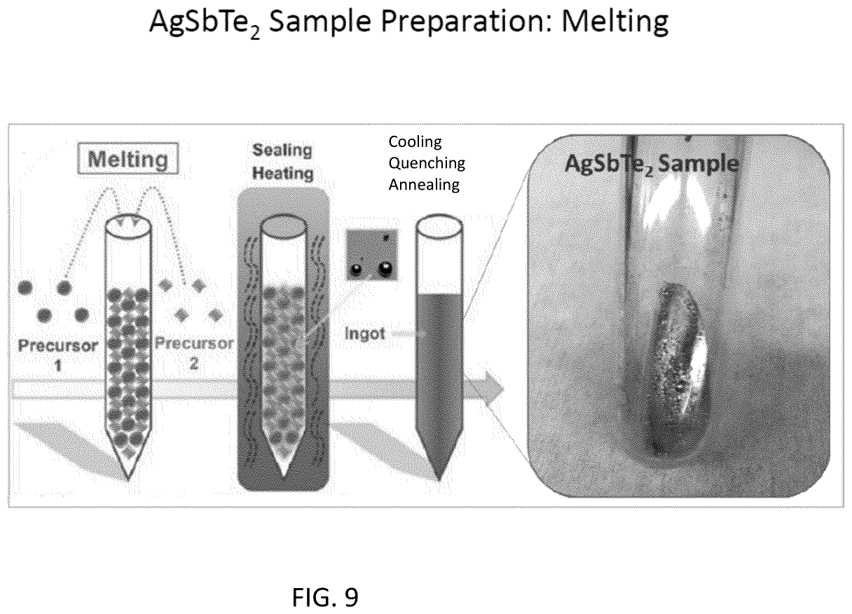

FIG. 9 shows an exemplary sample preparation method.

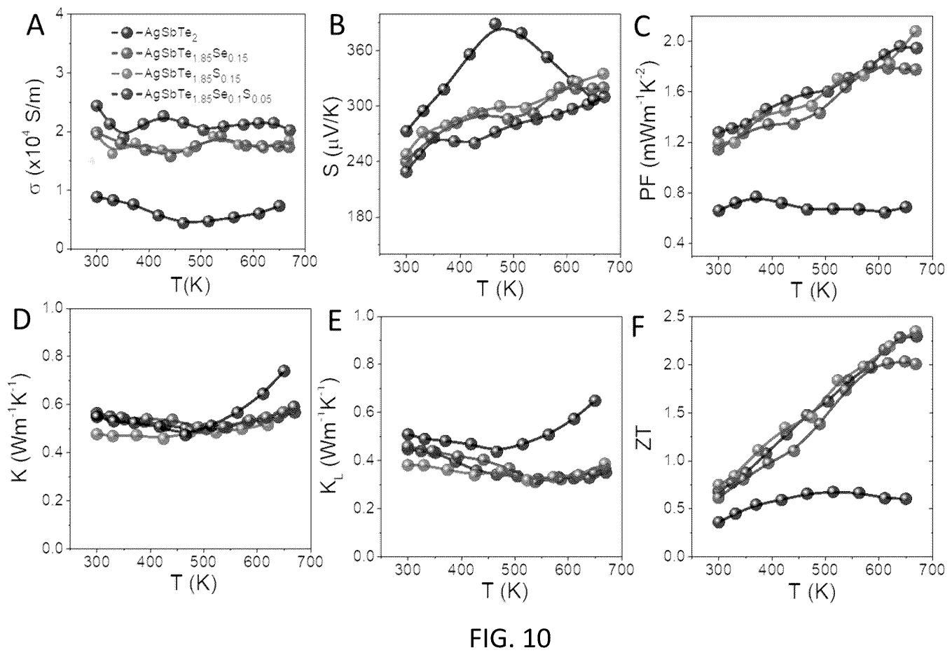

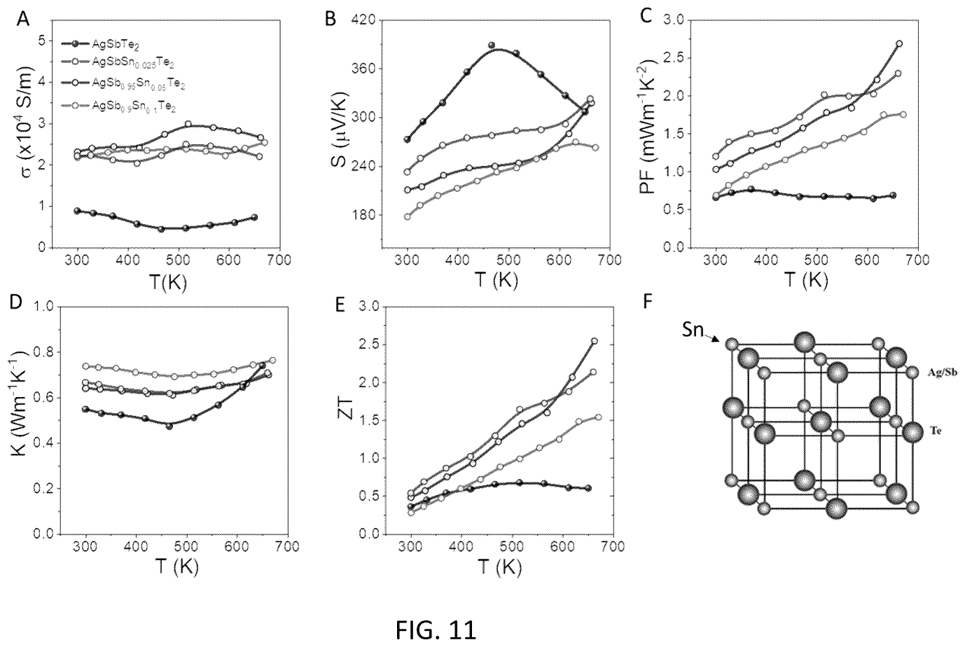

FIGS. 10 and 11 demonstrate how S/Se/Sn doping increases σ significantly throughout the temperature range from near room temperature to 673 K while still maintaining high Seebeck values. PF remains higher throughout the temperature range from near room temperature to 673 K than that of the pristine AgSbTe₂. The maximum of PF of AgSb₁₋ₓSnₓTe₂ is ˜25 μW cm⁻¹ K⁻² at 673 K. S/Se/Sn doping in in polycrystalline AgSbTe₂ further improves its thermoelectric performance by reducing κₜₒₜ and κ_{L}. As a result of this reduced kₜₒₜ and enhanced PF, zTof S/Se/Sn-dopedAgSbTe₂ improves tremendously.

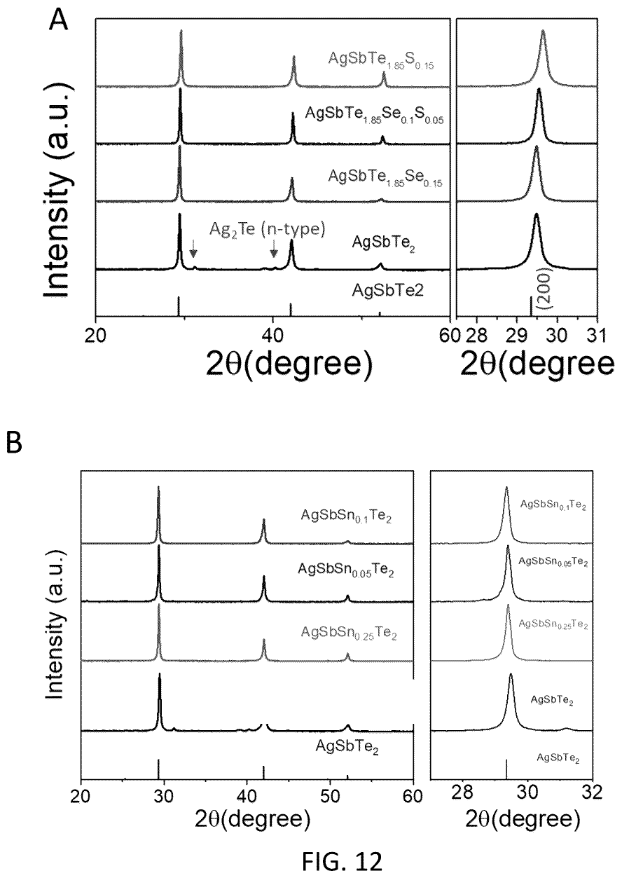

FIG. 12 demonstrates how XRD peaks of undoped AgSbTe₂ sample can be well indexed to cubic Fm3m AgSbTe₂ standard card, however, a minute impurity peak at 31.2° was detected, which was identified as Ag₂Te secondary phase. As a comparison, XRD peaks of sample prepared by S/Se/Sn doping are completely matched with the standard card, with no impurity phase detected. The result suggests that S/Se/Sn doping is able to produce a purer phase AgSbTe₂.

As can be appreciated from the present disclosure, the effect of selenium and sulfur doping on AgSbTe₂ thermoelectric provides technical advantages. One advantage of Se/S/Sn substitution in the AgSbTe₂ structure is that it can suppress formation of the impurity phase Ag₂Te in AgSbTe_{2-x-y}SeₓS_{y} and/or AgSb₁₋ₓSnₓTe₂. Powder X-ray diffraction and differential scanning calorimetry testing confirmed the gradual suppression of the Ag₂Te impurity phase with increasing Se concentration. Over two orders-of-magnitude difference in their carrier density was determined: for reference AgSbTe₂ sample n_{H}=1.2×10¹⁸ cm⁻³ and for S doped AgSbTe_{1.85}S_{0.15} (x=0, y=0.15) nH=2.0×10²⁰ cm⁻³ at 300 K. At the same time, the characteristic mobility behavior has an opposite trend. As a comparison, carrier concentration and mobility of S/Se/(Se+S)/Sn doped sample show stable and minor variation over the full temperature range. S/Se/(Se+S)/Sn-doped AgSbTe₂ compounds, however, exhibit two times higher electric conductivity compared with the pristine sample, while doped materials can still keep relatively high Seebeck coefficient, leading to an enhanced power factor as high as 2.0 at 673 K. The enlarged power factor at elevated temperatures for the S-doped compound can be attributed to increased electrical conductivity. All doped samples had lower total thermal conductivity and lower lattice thermal conductivity than ternary compound at high temperature. As a result, the peak value of zT=0.74 at 673 K was detected in the undoped sample, while the maximum zT value, as high as 2.3, was achieved at 673 K in a y=0.15 sample. This zT value is 310% higher than that of the undoped sample and one of the highest reported in literature. zT is directly related to thermal to electrical energy conversion and is also a main factor in thermal cooling. Thus, the inventive method can be used to produce materials exhibiting much higher power density generation.

The inventive method can solve the trade-off problem between Seebeck coefficient and electrical conductivity, which is a well-known dilemma in developing high-performance thermoelectric materials. Embodiments disclosed herein achieved a record figure-of-merit over 2.3 in p-type AgSbTe_{2-x-y}SeₓS_{y} and/or AgSb₁₋ₓSnₓTe₂ alloys, which is higher than the commercial bismuth antimony telluride (BiSbTe). A maximum heat-to electricity conversion efficiency of ≈13% was achieved under a temperature difference of 370 K for some embodiments. The inventive method and the materials it can produce, can have immediate impact on the design and development of high efficient solid state thermoelectric generators based on the breakthrough figure of merit alone.

It should be understood that the disclosure of a range of values is a disclosure of every numerical value within that range, including the end points. It should also be appreciated that some components, features, and/or configurations may be described in connection with only one particular embodiment, but these same components, features, and/or configurations can be applied or used with many other embodiments and should be considered applicable to the other embodiments, unless stated otherwise or unless such a component, feature, and/or configuration is technically impossible to use with the other embodiment. Thus, the components, features, and/or configurations of the various embodiments can be combined together in any manner and such combinations are expressly contemplated and disclosed by this statement.

It will be apparent to those skilled in the art that numerous modifications and variations of the described examples and embodiments are possible considering the above teachings of the disclosure. The disclosed examples and embodiments are presented for purposes of illustration only. Other alternate embodiments may include some or all of the features disclosed herein. Therefore, it is the intent to cover all such modifications and alternate embodiments as may come within the true scope of this invention, which is to be given the full breadth thereof.

It should be understood that modifications to the embodiments disclosed herein can be made to meet a particular set of design criteria. Therefore, while certain exemplary embodiments of the materials, compounds, formulations, and methods of using and making the same disclosed herein have been discussed and illustrated, it is to be distinctly understood that the invention is not limited thereto but may be otherwise variously embodied and practiced within the scope of the following claims.

1. A method of improving a thermoelectric property of a p-type semiconductor, the method comprising:
replacing a Te²⁻ in a lattice structure of a p-type semiconductor material with an anion to increase hole concentration of the p-type semiconductor material and/or to suppress formation of a Ag₂Te impurity phase of the p-type semiconductor material; and/or
replacing a Sb³⁺ in the lattice structure of the p-type semiconductor material with a cation to increase hole concentration of the p-type semiconductor material and/or to suppress formation of a Ag₂Te impurity phase of the p-type semiconductor material;
wherein the p-type semiconductor material includes a semiconductor material in addition to the AgSbTe₂ compound.

2. The method of claim 1, wherein:
replacing the Te²⁻ with the anion and/or replacing the Sb³⁺ with the cation increases hole concentration of the p-type semiconductor material and suppresses formation of a Ag₂Te impurity phase.

3. The method of claim 1, wherein:
the p-type semiconductor material includes an AgSbTe₂ compound.

4. (canceled)

5. The method of claim 3, wherein:
the cation has an ion radius that is less than an ion radius of Sb³⁺.

6. The method of claim 1, wherein:
the anion has an ion radius that is less than an ion radius of the Te²⁻.

7. The method of claim 1, wherein:
replacing the Te²⁻ involves replacing a first Te²⁻ in the lattice structure with a first anion and replacing a second Te²⁻ in the lattice structure with a second anion, the first anion being a different type of anion from the type of anion of the second anion; and
replacing the Sb⁺³ involves replacing a first Sb³⁺ in the lattice structure with a first cation and replacing a second Sb³⁺ in the lattice structure with a second cation, the first cation being the same type of cation as the type of cation of the second cation.

8. The method of claim 7, wherein:
the first anion has an ion radius that is less than an ion radius of the first Te²⁻ and the second anion has an ion radius that is less than an ion radius of the second Te²⁻; and
the first cation has an ion radius that is less than an ion radius of Sb³⁺ and the second cation has an ion radius that is less than an ion radius of Sb³⁺.

9. The method of claim 1, wherein:
the anion is Se²⁻ and/or S²⁻; and
the cation is Sn²⁺.

10. The method of claim 1, wherein:
the p-type semiconductor material includes an AgSbTe₂ compound;
the anion is Se²⁻ and/or S²⁻;
the cation is Sn²⁺; and
the doped AgSbTe₂ compound forms AgSbTeSe, AgSbTeS, AgSbSnTe, AgSbSnTeSe, and/or AgSbSnTeS.

11. The method of claim 7, wherein:
the first anion is Se²⁻ and the second anion is S²⁻; and
the first cation is Sn²⁺ and the second cation is Sn²⁺.

12. The method of claim 7, wherein:
the p-type semiconductor material includes an AgSbTe₂ compound;
the first anion is Se²⁻ and the second anion is S²⁻;
the first cation is Sn²⁺ and the second cation is Sn²⁺; and
the doped AgSbTe₂ compound forms AgSbTe_{2-x-y}SeₓS_{y} (0≤x≤0.3, 0≤y≤0.3) and/or AgSb₁₋ₓSnₓTe₂.

13. The method of claim 1, wherein:
Replacing the Te²⁻ and/or the Sb³⁺ in the lattice structure with the anion and/or the cation involves doping the p-type semiconductor material with the anion and/or the cation.

14. The method of claim 13, wherein:
doping involves diffusion and/or ion implantation.

15. A method of forming a p-type semiconductor material, the method comprising:
synthesizing an AgSbTe₂ compound;
during the synthesis, doping the AgSbTe₂ compound to replace a Te²⁻ and/or a Sb³⁺ in a lattice structure of the AgSbTe₂ compound with an anion and/or a cation to increase hole concentration of the AgSbTe₂ compound and/or to suppress formation of an Ag₂Te impurity phase of the AgSbTe₂ compound; and
forming a p-type semiconductor material with a semiconductor material and the doped AgSbTe₂ compound.

16. The method of claim 15, wherein:
the p-type semiconductor material consists of the doped AgSbTe₂ compound;
the p-type semiconductor material consists essentially of the doped AgSbTe₂ compound; or
the p-type semiconductor material comprises the doped AgSbTe₂ compound.

17. A p-type semiconductor material, comprising:
an AgSbTe₂ compound having a lattice structure, wherein at least one Te²⁻ site and/or at least one Sb³⁺ site in the lattice structure has an anion in place of the Te²⁻ and/or a cation in place of the Sb³⁺, the anion having an ion radius that is less than an ion radius of Te²⁻, the cation having an ion radius that is less than an ion radius of Sb³⁺;
a semiconductor material in addition to the AgSbTe₂ compound.

18. (canceled)

19. The p-type semiconductor material of claim 17, wherein:
the anion is Se²⁻ and/or S²⁻; and
the cation is Sn²⁺.

20. A thermoelectric device, comprising:
a p-type semiconductor material, the p-type semiconductor material including a semiconductor material and an AgSbTe₂ compound having a lattice structure, wherein at least one Te²⁻ site and/or at least one Sb³⁺ site in the lattice structure has an anion in place of the Te²⁻ and/or a cation in place of the Sb³⁺, the anion having an ion radius that is less than an ion radius of Te²⁻, the cation having an ion radius that is less than an ion radius of Sb³⁺.
